(19) United States
(12) Patent Application Publication
(10) Pub. No.: US 2025/0324715 A1
(43) Pub. Date: Oct. 16, 2025

(54) TRANSISTOR STRUCTURE AND MANUFACTURING METHOD THEREOF

(71) Applicant: United Microelectronics Corp., Hsinchu (TW)

(72) Inventor: Shin-Hung Li, Nantou County (TW)

(73) Assignee: United Microelectronics Corp., Hsinchu (TW)

(21) Appl. No.: 18/657,716

(22) Filed: May 7, 2024

(30) Foreign Application Priority Data
Apr. 10, 2024 (TW) 113113289

(51) Int. Cl. H01L 29/423; H01L 21/762; H01L 29/40

(52) U.S. Cl. CPC H10D 64/514; H01L 21/76202; H01L 21/76224; H10D 64/01; H10D 64/512; H10D 64/518

(57) ABSTRACT

A transistor structure including a substrate, an isolation structure, a gate, and a gate dielectric layer is provided. The isolation structure is located in the substrate. The isolation structure defines an active region in the substrate. The isolation structure protrudes from a top surface of the substrate to form a recess above the active region. The gate is located on the substrate. The gate includes a first portion and a second portion. The first portion is located in the recess. The second portion is located on the first portion. The second portion is located directly above a portion of the isolation structure. The gate dielectric layer is located between the first portion and the substrate, between the first portion and the isolation structure, and between the second portion and the isolation structure.

### CROSS-REFERENCE TO RELATED APPLICATION

This application claims the priority benefit of Taiwan application serial no. 113113289, filed on Apr. 10, 2024. The entirety of the above-mentioned patent application is hereby incorporated by reference herein and made a part of specification.

### BACKGROUND

### Technical Field

The invention relates to a semiconductor structure and a manufacturing method thereof, and particularly relates to a transistor structure and a manufacturing method thereof.

### Description of Related Art

The transistor device is an important device in the integrated circuit. However, how to further improve the electrical performance of the transistor device (such as reducing the off-current (I_{off}) and reducing the power consumption) is the goal of continuous efforts at present.

### SUMMARY

The invention provides a transistor structure and a manufacturing method thereof, which can improve the electrical performance of the transistor structure.

The invention provides a transistor structure, which includes a substrate, an isolation structure, a gate, and a gate dielectric layer. The isolation structure is located in the substrate. The isolation structure defines an active region in the substrate. The isolation structure protrudes from a top surface of the substrate to form a recess above the active region. The gate is located on the substrate. The gate includes a first portion and a second portion. The first portion is located in the recess. The second portion is located on the first portion. The second portion is located directly above a portion of the isolation structure. The gate dielectric layer is located between the first portion and the substrate, between the first portion and the isolation structure, and between the second portion and the isolation structure.

According to an embodiment of the invention, in the transistor structure, the width of the first portion may be smaller than the width of the second portion.

According to an embodiment of the invention, in the transistor structure, the width of the first portion may be smaller than the width of the active region.

According to an embodiment of the invention, in the transistor structure, the cross-sectional shape of the gate may include a T-shape.

According to an embodiment of the invention, in the transistor structure, the cross-sectional shape of a portion of the gate dielectric layer located between the first portion and the substrate and between the first portion and the isolation structure may include a U-shape.

According to an embodiment of the invention, in the transistor structure, the isolation structure may have a first upper surface and a second upper surface. The first upper surface is located between the second upper surface and the gate. The first upper surface may be higher than the second upper surface.

According to an embodiment of the invention, in the transistor structure, the isolation structure may have a notch. The notch may be located on one side of the isolation structure away from the active region.

According to an embodiment of the invention, in the transistor structure, the gate dielectric layer may include a first dielectric layer, a second dielectric layer, and a third dielectric layer. The first dielectric layer is located on the substrate in the active region. The second dielectric layer is located on the first dielectric layer. The third dielectric layer is located on the second dielectric layer, the sidewall of the isolation structure, and the upper surface of the isolation structure.

According to an embodiment of the invention, in the transistor structure, the first dielectric layer, the second dielectric layer, and a portion of the third dielectric layer may be located in the recess.

According to an embodiment of the invention, the transistor structure may further include a spacer. The spacer is located on the sidewall of the gate dielectric layer.

According to an embodiment of the invention, in the transistor structure, the spacer may be further located on the sidewall of the second portion.

According to an embodiment of the invention, in the transistor structure, the spacer may be further located on the sidewall of the isolation structure and the upper surface of the isolation structure.

The invention provides a manufacturing method of a transistor structure, which includes the following steps. A substrate is provided. An isolation structure is formed in substrate. The isolation structure defines an active region in the substrate. The isolation structure protrudes from the top surface of the substrate to form a recess above the active region. A gate is formed on the substrate. The gate includes a first portion and a second portion. The first portion is located in the recess. The second portion is located on the first portion. The second portion is located directly above a portion of the isolation structure. A dielectric layer is formed between the first portion and the substrate, between the first portion and the isolation structure, and between the second portion and the isolation structure.

According to an embodiment of the invention, in the manufacturing method of a transistor structure, the gate dielectric layer may include a first dielectric layer, a second dielectric layer, and a third dielectric layer. The first dielectric layer is located on the substrate in the active region. The second dielectric layer is located on the first dielectric layer. The third dielectric layer is located on the second dielectric layer, the sidewall of the isolation structure, and the upper surface of the isolation structure.

According to an embodiment of the invention, in the manufacturing method of the transistor structure, the method of forming the first dielectric layer is, for example, a thermal oxidation method.

According to an embodiment of the invention, in the manufacturing method of the transistor structure, the method of forming the second dielectric layer is, for example, a thermal oxidation method.

According to an embodiment of the invention, in the manufacturing method of the transistor structure, the method of forming the third dielectric layer may include the following steps. A dielectric material layer is conformally formed on the isolation structure and the second dielectric layer. The dielectric material layer is patterned to form the third dielectric layer.

According to an embodiment of the invention, in the manufacturing method of the transistor structure, the method of forming the dielectric material layer is, for example, an atomic layer deposition (ALD) method or a chemical vapor deposition (CVD) method.

According to an embodiment of the invention, in the manufacturing method of the transistor structure, the first dielectric layer, the second dielectric layer, and a portion of the third dielectric layer may be located in the recess.

According to an embodiment of the invention, the manufacturing method of the transistor structure may further include the following steps. The isolation structure is patterned to form a notch in the isolation structure.

Based on the above description, in the transistor structure and the manufacturing method thereof according to the invention, the gate dielectric layer is located between the first portion and the substrate, between the first portion and the isolation structure, and between the second portion and the isolation structure. Therefore, the first portion of the gate can have a smaller gate width, and the corner thinning of the gate dielectric layer can be prevented, thereby reducing the off-current (I_{off}), the power consumption, and the subthreshold hump effect of the transistor structure. In this way, the transistor structure can have better electrical performance.

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are cross-sectional views of a manufacturing process of a transistor structure according to some embodiments of the invention.

### DESCRIPTION OF THE EMBODIMENTS

The embodiments are described in detail below with reference to the accompanying drawings, but the embodiments are not intended to limit the scope of the invention. For the sake of easy understanding, the same components in the following description will be denoted by the same reference symbols. In addition, the drawings are for illustrative purposes only and are not drawn to the original dimensions. In fact, the dimensions of the various features may be arbitrarily increased or reduced for clarity of discussion.

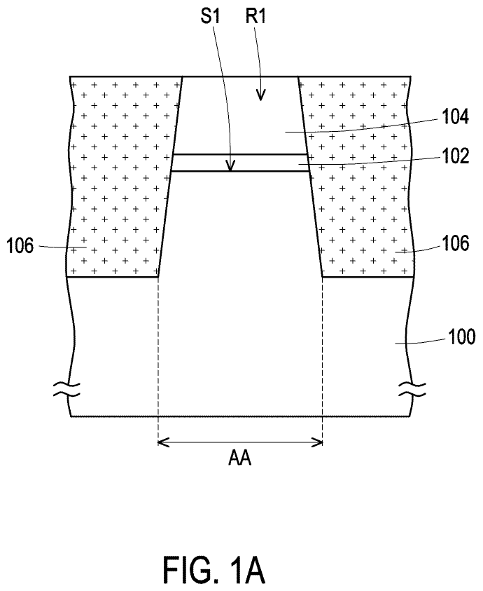

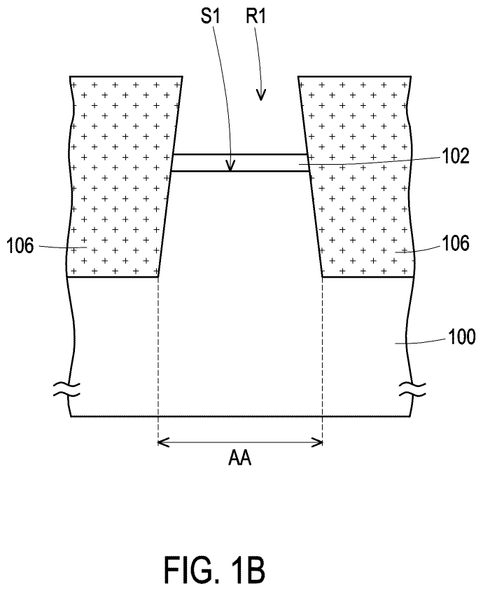

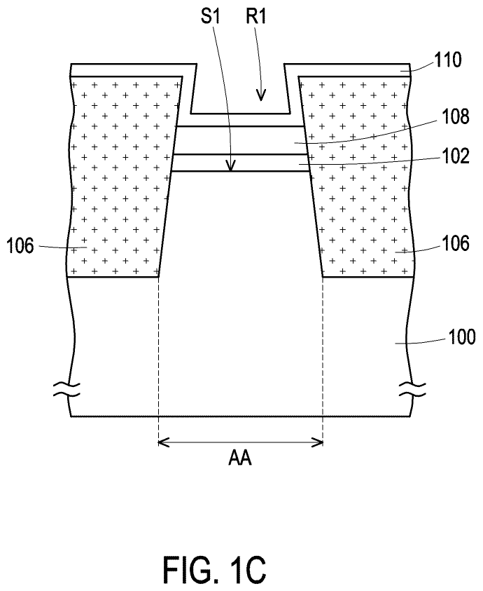

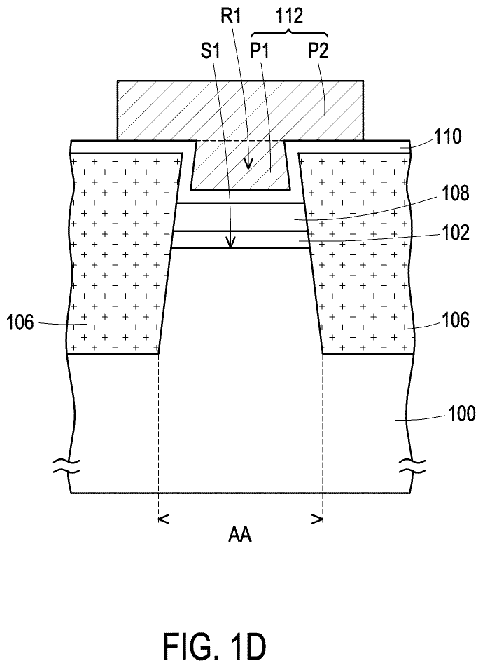

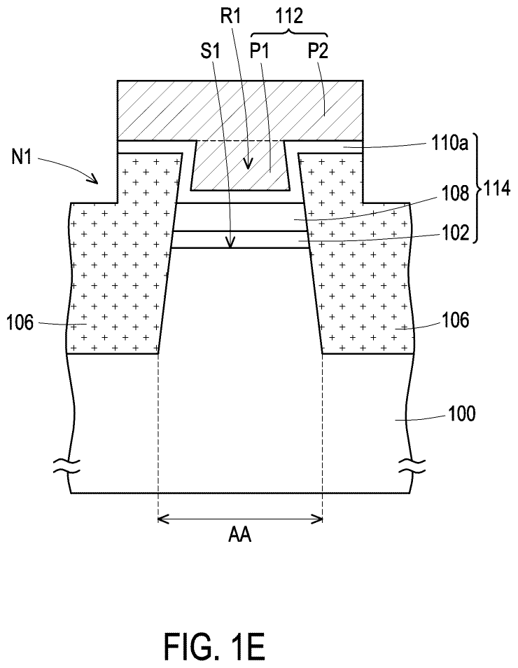

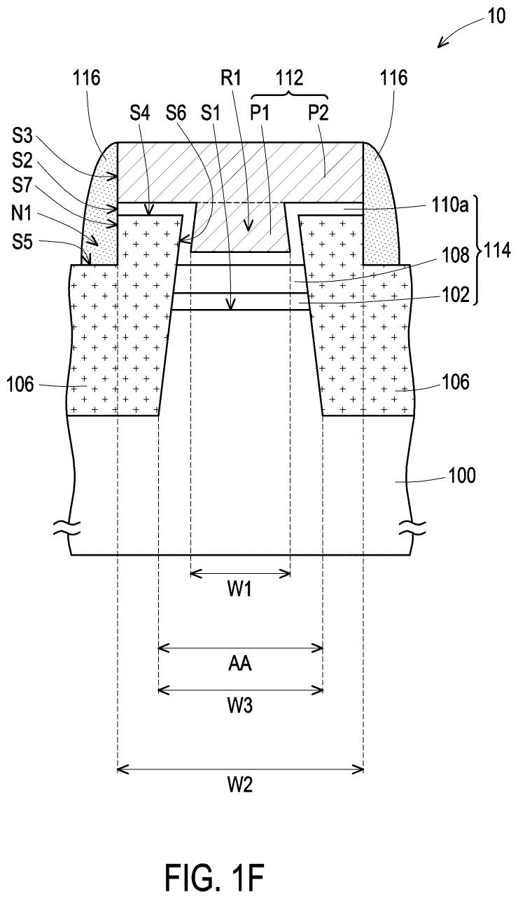

FIG. 1A to FIG. 1F are cross-sectional views of a manufacturing process of a transistor structure according to some embodiments of the invention.

Referring to FIG. 1A, a substrate 100 is provided. In some embodiments, the substrate 100 may be a semiconductor substrate such as a silicon substrate. A dielectric layer 102 may be formed on the substrate 100. In some embodiments, the material of the dielectric layer 102 is, for example, silicon oxide. In some embodiments, the method of forming the dielectric layer 102 is, for example, a thermal oxidation method. A dielectric layer 104 may be formed on the dielectric layer 102. In some embodiments, the material of the dielectric layer 104 is, for example, silicon nitride. In some embodiments, the method of forming the dielectric layer 104 is, for example, a chemical vapor deposition method.

An isolation structure 106 is formed in the substrate 100. The isolation structure 106 may be further formed in the dielectric layer 104 and the dielectric layer 102. The isolation structure 106 defines an active region AA in the substrate 100. The isolation structure 106 protrudes from the top surface S1 of the substrate 100 to form a recess R1 above the active region AA. In some embodiments, the recess R1 may be a space defined by a portion of the isolation structure 106 protruding from the top surface S1 of the substrate 100. The dielectric layer 104 and the dielectric layer 102 may be located in the recess R1. In some embodiments, the isolation structure 106 may be a shallow trench isolation (STI) structure. In some embodiments, the material of the isolation structure 106 is, for example, silicon oxide. In some embodiments, the isolation structure 106 may be formed by a shallow trench isolation structure process.

Referring to FIG. 1B, the dielectric layer 104 may be removed. In some embodiments, the method of removing the dielectric layer 104 is, for example, a wet etching method.

Referring to FIG. 1C, a dielectric layer 108 may be formed on the dielectric layer 102. In some embodiments, the material of the dielectric layer 108 is, for example, silicon oxide. In some embodiments, the method of forming the dielectric layer 108 is, for example, a thermal oxidation method.

A dielectric material layer 110 may be conformally formed on the isolation structure 106 and the dielectric layer 108. In some embodiments, the material of the dielectric material layer 110 is, for example, silicon oxide. In some embodiments, the method of forming the dielectric material layer 110 is, for example, an atomic layer deposition method or a chemical vapor deposition method.

Referring to FIG. 1D, a gate 112 is formed on the substrate 100. The gate 112 includes a first portion P1 and a second portion P2. The first portion P1 is located in the recess R1. In some embodiments, a portion of the first portion P1 may be located outside the recess R1. The second portion P2 is located on the first portion P1. The second portion P2 is located directly above a portion of the isolation structure 106. In some embodiments, the material of the gate 112 is, for example, doped polysilicon. In some embodiments, the method of forming the gate 112 may include the following steps. First, a gate material layer (not shown) may be formed on the dielectric material layer 110. Then, the gate material layer may be patterned by a lithography process and an etching process to form the gate 112.

Referring to FIG. 1E, the dielectric material layer 110 may be patterned to form a dielectric layer 110a. In some embodiments, a portion of the dielectric material layer 110 is removed by using the gate 112 as a mask to form the dielectric layer 110a. In some embodiments, the method of removing the portion of the dielectric material layer 110 is, for example, a dry etching method.

In some embodiments, the isolation structure 106 may be patterned to form a notch N1 in the isolation structure 106. In some embodiments, a portion of the isolation structure 106 is removed by using the gate 112 as a mask to form the notch N1. In some embodiments, the method of removing the portion of the isolation structure 106 is, for example, a dry etching method.

By the above method, a gate dielectric layer 114 may be formed between the first portion P1 and the substrate 100, between the first portion P1 and the isolation structure 106, and between the second portion P2 and the isolation structure 106. The gate dielectric layer 114 may include the dielectric layer 102, the dielectric layer 108, and the dielectric layer 110a.

Referring to FIG. 1F, a spacer 116 may be formed on the sidewall S2 of the gate dielectric layer 114 (e.g., the sidewall of the dielectric layer 110a), the sidewall S3 of the second portion P2, and the isolation structure 106. The spacer 116 may be a single-layer structure or a multilayer structure. In some embodiments, the material of the spacer 116 is, for example, silicon oxide, silicon nitride, or a combination thereof. In some embodiments, the method of forming the spacer 116 may include the following steps. First, a spacer material layer (not shown) may be conformally formed on the gate 112, the gate dielectric layer 114, and the isolation structure 106. Then, an etch-back process may be performed on the spacer material layer to form the spacer 116.

Hereinafter, the transistor structure 10 of the above embodiment will be described with reference to FIG. 1F. In addition, although the method for forming the transistor structure 10 is described by taking the above method as an example, the invention is not limited thereto.

Referring to FIG. 1F, a transistor structure 10 includes a substrate 100, an isolation structure 106, a gate 112, and a gate dielectric layer 114. In addition, although not shown in the figure, the substrate 100 may have required doped regions (e.g., source region, drain region and/or well region) therein.

The isolation structure 106 is located in the substrate 100. The isolation structure 106 defines an active region AA in the substrate 100. The isolation structure 106 protrudes from the top surface S1 of the substrate 100 to form a recess R1 above the active region AA. In some embodiments, the isolation structure 106 may have an upper surface S4 and an upper surface S5. The upper surface S4 is located between the upper surface S5 and the gate 112. The upper surface S4 may be higher than the upper surface S5. In some embodiments, the isolation structure 106 may have a notch N1. The notch N1 may be located on one side of the isolation structure 106 away from the active region AA.

The gate 112 is located on the substrate 100. The gate 112 includes a first portion P1 and a second portion P2. The first portion P1 is located in the recess R1. The second portion P2 is located on the first portion P1. The second portion P2 is located directly above a portion of the isolation structure 106. In some embodiments, the width W1 of the first portion P1 may be smaller than the width W2 of the second portion P2. In some embodiments, the cross-sectional shape of the gate 112 may include a T-shape. In some embodiments, the width W1 of the first portion P1 may be smaller than the width W3 of the active region AA.

In the transistor structure 10, the “channel length direction” may be defined as a direction parallel to the arrangement direction of the source region (not shown) and the drain region (not shown), and the “channel width direction” intersects the “channel length direction”. In some embodiments, the “channel width direction” may be perpendicular to the “channel length direction”. The “channel length” and the “channel width” of the transistor structure 10 may be respectively defined as “the length of the channel region of the transistor structure 10 in the channel length direction” and “the width of the channel region of the transistor structure 10 in the channel width direction”. In some embodiments, the width W3 of the active region AA may be the “channel width”. In some embodiments, the “gate width” of the gate 112 may be defined as “the width of the gate 112 in the channel width direction”.

The gate dielectric layer 114 is located between the first portion P1 and the substrate 100, between the first portion P1 and the isolation structure 106, and between the second portion P2 and the isolation structure 106. In some embodiments, the cross-sectional shape of a portion of the gate dielectric layer 114 located between the first portion P1 and the substrate 100 and between the first portion P1 and the isolation structure 106 may include a U-shape.

In some embodiments, the gate dielectric layer 114 may include a dielectric layer 102, a dielectric layer 108, and a dielectric layer 110a. The dielectric layer 102 is located on the substrate 100 in the active region AA. The dielectric layer 108 located on the dielectric layer 102. The dielectric layer 110a is located on the dielectric layer 108, the sidewall S6 of the isolation structure 106, and the upper surface S4 of the isolation structure 106. The dielectric layer 102, the dielectric layer 108, and a portion of the dielectric layer 110a may be located in the recess R1.

In some embodiments, the transistor structure 10 may further include a spacer 116. The spacer 116 is located on the sidewall S2 of the gate dielectric layer 114. In some embodiments, the spacer 116 may be further located on the sidewall S3 of the second portion P2. In some embodiments, the spacer 116 may be further located on the sidewall S7 of the isolation structure 106 and the upper surface S5 of the isolation structure 106.

Based on the above embodiments, in the transistor structure 10 and the manufacturing method thereof, the gate dielectric layer 114 is located between the first portion P1 and the substrate 100, between the first portion P1 and the isolation structure 106, and between the second portion P2 and the isolation structure 106. Therefore, the first portion P1 of the gate 112 can have a smaller gate width, and the corner thinning of the gate dielectric layer 114 can be prevented, thereby reducing the off-current (I_{off}), the power consumption, and the subthreshold hump effect of the transistor structure 10. In this way, the transistor structure 10 can have better electrical performance.

In summary, in the transistor structure and the manufacturing method thereof in the aforementioned embodiments, a transistor structure includes a substrate, an isolation structure, a gate, and a gate dielectric layer. The isolation structure is located in the substrate. The isolation structure defines an active region in the substrate. The isolation structure protrudes from a top surface of the substrate to form a recess above the active region. The gate is located on the substrate. The gate includes a first portion and a second portion. The first portion is located in the recess. The second portion is located on the first portion. The second portion is located directly above a portion of the isolation structure. The gate dielectric layer is located between the first portion and the substrate, between the first portion and the isolation structure, and between the second portion and the isolation structure. Therefore, the first portion of the gate can have a smaller gate width, and the corner thinning of the gate dielectric layer can be prevented, thereby reducing the off-current (I_{off}), the power consumption, and the subthreshold hump effect of the transistor structure. In this way, the transistor structure can have better electrical performance.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A transistor structure, comprising:
a substrate;
an isolation structure located in the substrate and defining an active region in the substrate, wherein the isolation structure protrudes from a top surface of the substrate to form a recess above the active region;
a gate located on the substrate and comprising:
a first portion located in the recess; and
a second portion located on the first portion and located directly above a portion of the isolation structure; and
a gate dielectric layer located between the first portion and the substrate, between the first portion and the isolation structure, and between the second portion and the isolation structure.

2. The transistor structure according to claim 1, wherein the width of the first portion is smaller than a width of the second portion.

3. The transistor structure according to claim 1, wherein a width of the first portion is smaller than a width of the active region.

4. The transistor structure according to claim 1, wherein a cross-sectional shape of the gate comprises a T-shape.

5. The transistor structure according to claim 1, wherein a cross-sectional shape of a portion of the gate dielectric layer located between the first portion and the substrate and between the first portion and the isolation structure comprises a U-shape.

6. The transistor structure according to claim 1, wherein the isolation structure has a first upper surface and a second upper surface, the first upper surface is located between the second upper surface and the gate, and the first upper surface is higher than the second upper surface.

7. The transistor structure according to claim 1, wherein the isolation structure has a notch, and the notch is located on one side of the isolation structure away from the active region.

8. The transistor structure according to claim 1, wherein the gate dielectric layer comprises:
a first dielectric layer located on the substrate in the active region;
a second dielectric layer located on the first dielectric layer; and
a third dielectric layer located on the second dielectric layer, a sidewall of the isolation structure, and an upper surface of the isolation structure.

9. The transistor structure according to claim 8, wherein the first dielectric layer, the second dielectric layer, and a portion of the third dielectric layer are located in the recess.

10. The transistor structure according to claim 1, further comprising:
a spacer located on a sidewall of the gate dielectric layer.

11. The transistor structure according to claim 10, wherein the spacer is further located on a sidewall of the second portion.

12. The transistor structure according to claim 10, wherein the spacer is further located on a sidewall of the isolation structure and an upper surface of the isolation structure.

13. A manufacturing method of a transistor structure, comprising:
providing a substrate;
forming an isolation structure in the substrate, wherein the isolation structure defines an active region in the substrate, and the isolation structure protrudes from a top surface of the substrate to form a recess above the active region;
forming a gate on the substrate, wherein the gate comprises:
a first portion located in the recess; and
a second portion located on the first portion and located directly above a portion of the isolation structure; and
forming a gate dielectric layer between the first portion and the substrate, between the first portion and the isolation structure, and between the second portion and the isolation structure.

14. The manufacturing method of the transistor structure according to claim 13, wherein the gate dielectric layer comprises:
a first dielectric layer located on the substrate in the active region;
a second dielectric layer located on the first dielectric layer; and
a third dielectric layer located on the second dielectric layer, a sidewall of the isolation structure, and an upper surface of the isolation structure.

15. The manufacturing method of the transistor structure according to claim 14, wherein a method of forming the first dielectric layer comprises a thermal oxidation method.

16. The manufacturing method of the transistor structure according to claim 14, wherein a method of forming the second dielectric layer comprises a thermal oxidation method.

17. The manufacturing method of the transistor structure according to claim 14, wherein a method of forming the third dielectric layer comprises:
conformally forming a dielectric material layer on the isolation structure and the second dielectric layer; and
patterning the dielectric material layer to form the third dielectric layer.

18. The manufacturing method of the transistor structure according to claim 17, wherein a method of forming the dielectric material layer comprises an atomic layer deposition method or a chemical vapor deposition method.

19. The manufacturing method of the transistor structure according to claim 14, wherein the first dielectric layer, the second dielectric layer, and a portion of the third dielectric layer are located in the recess.

20. The manufacturing method of the transistor structure according to claim 13, further comprising:
patterning the isolation structure to form a notch in the isolation structure.
